(19) United States
(12) Patent Application Publication
(10) Pub. No.: US 2020/0294877 A1
(43) Pub. Date: Sep. 17, 2020

(54) Molded Semiconductor Package with Mold Surface Modification

(71) Applicant: Infineon Technologies AG, Neubiberg (DE)

(72) Inventors: Valerie Vivares, Munich (DE); Sergey Ananiev, Ottobrunn (DE)

(21) Appl. No.: 16/355,245

(22) Filed: Mar. 15, 2019

(51) Int. Cl. H01L 23/31; H01L 23/495; H01L 23/00; H01L 21/48; H01L 21/56; B29C 70/68

(52) U.S. Cl. CPC H01L 23/3114; H01L 23/49503; H01L 23/4952; H01L 23/49541; B29K 2063/00; H01L 21/4825; H01L 21/565; B29C 70/68; B29C 70/681; H01L 23/562

(57) ABSTRACT

A molded semiconductor package includes a semiconductor die embedded in a mold compound, and a plurality of metal leads embedded in the mold compound and electrically connected to the semiconductor die. A first plurality of features is formed in an exterior surface of the mold compound. The first plurality of features disrupts a planarity of the exterior surface of the mold compound and is arranged along a direction which is transverse to a lengthwise extension of the plurality of metal leads. Corresponding methods of manufacturing such a molded semiconductor package are also described.

### BACKGROUND

Electrical connection between a semiconductor die (chip) embedded in a mold compound and a substrate such as a printed circuit board (PCB) is often done by metal leads. The metal leads are typically connected to the embedded die with thin bond wires. Over time, the exterior surface of the mold compound embedding the semiconductor die may oxidize. The oxidation process may be accelerated under elevated stress conditions. The oxidized surface of the mold compound shrinks, inducing forces such as tensile, compressive and shear inside the molded package. The forces can cause separation (delamination) of the mold compound from the tips of the metal leads, and can destroy electrical connections between the bond wires and the embedded die as well as between the bond wires and the metal leads. The delamination is limited to within the mold compound, where the main concern is complete failure. Forces applied to thin bond wires can shear the bond wires from the metal leads and/or the die. The delamination force itself induces a shearing force, and delamination-induced forces may also impact the embedded die. An air gap that results due to delamination may alter electrical performance of the device, e.g., in the case of pressure sensors. Moisture may also enter the molded package and vapor may displace some of the mold compound, causing a popcorn-like effect.

Thus, there is a need for an improved molded semiconductor package that is more immune to the oxidative effects on the mold compound.

### SUMMARY

According to an embodiment of a molded semiconductor package, the molded semiconductor package comprises: a semiconductor die embedded in a mold compound; a plurality of metal leads embedded in the mold compound and electrically connected to the semiconductor die; and a first plurality of features formed in an exterior surface of the mold compound, the first plurality of features disrupting a planarity of the exterior surface of the mold compound and being arranged along a direction which is transverse to a lengthwise extension of the plurality of metal leads.

The first plurality of features formed in the exterior surface of the mold compound may comprise a first plurality of grooves formed in the exterior surface of the mold compound.

At least one groove of the first plurality of grooves may be continuous and surround the semiconductor die in a vertical projection which is perpendicular to the exterior surface of the mold compound.

Separately or in combination, at least one groove of the first plurality of grooves may be segmented into groove segments which are separated from one another by an undisrupted portion of the exterior surface of the mold compound.

Each groove which is segmented into groove segments may have four linear groove segments each one of which runs along a different side of the semiconductor die in a vertical projection which is perpendicular to the exterior surface of the mold compound.

Each groove which is segmented into groove segments may instead have a plurality of curvilinear groove segments surrounding the semiconductor die in a vertical projection which is perpendicular to the exterior surface of the mold compound.

Separately or in combination, the first plurality of grooves may comprise a plurality of concentric squares centered on the semiconductor die and surrounding the semiconductor die in a vertical projection which is perpendicular to the exterior surface of the mold compound.

Separately or in combination, the first plurality of grooves may comprise a plurality of concentric circles centered on the semiconductor die and surrounding the semiconductor die in a vertical projection which is perpendicular to the exterior surface of the mold compound.

Separately or in combination, the first plurality of features formed in the exterior surface of the mold compound may comprise a first plurality of dimples formed in the exterior surface of the mold compound, and the first plurality of dimples may be arranged in rows which run along a direction which is transverse to the lengthwise extension of the plurality of metal leads.

Separately or in combination, the first plurality of features formed in the exterior surface of the mold compound may comprise a first plurality of grooves formed as a grid in the exterior surface of the mold compound.

Separately or in combination, the first plurality of features may disrupt the planarity of the exterior surface of the mold compound above the plurality of metal leads.

Separately or in combination, the molded semiconductor package may further comprise a second plurality of features formed in the exterior surface of the mold compound, and the second plurality of features may disrupt the planarity of the exterior surface of the mold compound above the semiconductor die.

According to an embodiment of a method of manufacturing a molded semiconductor package, the method comprises: electrically connecting a plurality of metal leads to a semiconductor die; after electrically connecting the plurality of metal leads to the semiconductor die, embedding the semiconductor die and the plurality of metal leads in a mold compound; and forming a first plurality of features in an exterior surface of the mold compound, the first plurality of features disrupting a planarity of the exterior surface of the mold compound and being arranged along a direction which is transverse to a lengthwise extension of the plurality of metal leads.

The first plurality of features may be formed in the exterior surface of the mold compound by laser etching the exterior surface of the mold compound, during embedding of the semiconductor die and the plurality of metal leads in the mold compound, and/or by polishing the exterior surface of the mold compound.

Separately or in combination, forming the first plurality of features in the exterior surface of the mold compound may comprise forming a first plurality of continuous and/or segmented grooves in the exterior surface of the mold compound.

Separately or in combination, forming the first plurality of features in the exterior surface of the mold compound may comprise forming a plurality of continuous and/or segmented concentric squares or circles in the exterior surface of the mold compound and which are centered on the semiconductor die and surround the semiconductor die in a vertical projection which is perpendicular to the exterior surface of the mold compound.

Separately or in combination, forming the first plurality of features in the exterior surface of the mold compound may comprise forming a first plurality of dimples in the exterior surface of the mold compound, the first plurality of dimples being arranged in rows which run along a direction which is transverse to the lengthwise extension of the plurality of metal leads.

Separately or in combination, the first plurality of features may disrupt the planarity of the exterior surface of the mold compound above the plurality of metal leads and the method may further comprise forming a second plurality of features in the exterior surface of the mold compound, the second plurality of features disrupting the planarity of the exterior surface of the mold compound above the semiconductor die.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1 through 7 illustrate respective top plan views of different embodiments of molded semiconductor packages in which the planarity of the exterior surface of the mold compound is disrupted.

FIG. 8 illustrates stress forces acting on a metal lead of a molded semiconductor package and caused by oxidation of the exterior surface of the mold compound.

FIG. 9 illustrates the normal tensile stress component of the total interface stress acting on the metal leads, and FIG. 10 illustrates the shear stress component of the total interface stress acting on the metal leads.

FIGS. 11 through 13 illustrate respective partial sectional views of additional embodiments of molded semiconductor packages in which the planarity of the exterior surface of the mold compound is disrupted.

FIGS. 14A illustrates a partial top plan view of another embodiment of a molded semiconductor package in which the planarity of the exterior surface of the mold compound is disrupted, and FIG. 14B illustrates a partial sectional view of the molded semiconductor package taken along the line labelled A-A′ in FIG. 14A.

FIGS. 15A through 15C illustrate respective partial sectional views associated with different stages of a method of manufacturing a molded semiconductor package in which the planarity of the exterior surface of the mold compound is disrupted.

### DETAILED DESCRIPTION

The embodiments described herein provide a molded semiconductor package in which the planarity of the exterior surface of the mold compound is disrupted. In some cases, the exterior surface of the mold compound may oxidize over time. By disrupting the planarity of the exterior surface of the mold compound, the integral characteristic of the oxide shrinkage is reduced which in turn reduces the delamination force. This is particularly beneficial near sensitive regions of the package such as the interface between the mold compound and the tips of the package metal leads, the interface between bond wires and metal leads of the package, the interface between bond wires and a semiconductor die embedded in the mold compound, etc. Various surface features and configurations, as well as methods for forming the surface features in the various configurations are provided. The surface features, configurations and corresponding methods of manufacturing the same described herein may be combined with each other, unless specifically noted otherwise.

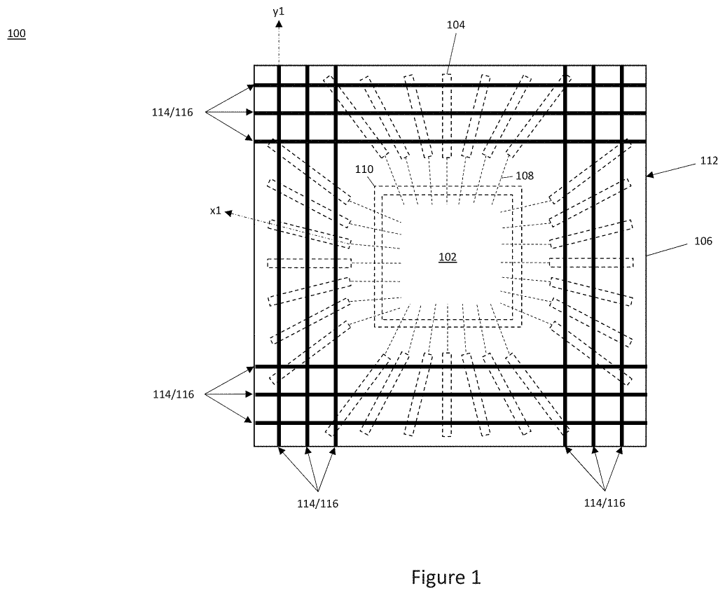

FIG. 1 illustrates a top plan view of an embodiment of a molded semiconductor package 100 in which the planarity of the exterior surface of the mold compound is disrupted, reducing the integral characteristic of the oxide shrinkage and therefore reducing the delamination force. The semiconductor package 100 includes a semiconductor die 102 and metal leads 104 embedded in a mold compound 106. The metal leads 104 are electrically connected to the semiconductor die 102, e.g., via bond wires 108 or other types of connectors such as metal clips, wire ribbons, etc. In an embodiment, the metal leads 104 are part of a metal leadframe and the semiconductor die 102 is attached to a die pad 110 of the metal leadframe. Other types of metal leads may be used. Any typical mold compound may be used such as, but not limited to, an epoxy such as a thermoset polymer having a resin base.

The molded semiconductor package 100 may be a leadless or leaded package. In the case of a leaded package, the metal leads 104 protrude from one or more side faces 112 of the mold compound 106 around the perimeter of the mold compound 106, and may either go through a PCB or other type of substrate and be soldered on the substrate backside (through-hole) or directly to the substrate front side (surface mount). In the case of a leadless package, the metal leads 104 provide contact points at the backside (out of view) of the package 100 instead of along the perimeter of the mold compound 106.

In either case, each semiconductor die 102 embedded in the mold compound 106 may be a power transistor die, logic die, passive die, etc. The molded semiconductor package 100 may include a single semiconductor die 102 or more than one die 102. One semiconductor die 102 is shown in FIG. 1 for ease of illustration only. The semiconductor die 102, metal leads 104, bond wires 108 and die pad 110 are illustrated with respective dashed boxes in FIG. 1 since each of these components is embedded in the mold compound 106. The metal leads 104 are illustrated generically, and may be of either the leaded or leadless type.

The exterior surface of the mold compound 106 may oxidize over time. The delamination force created by the oxidation of the mold compound 106 can be reduced by reducing the integral characteristic of the oxide shrinkage. The integral characteristic of the oxide shrinkage is reduced by forming features 114 in the exterior surface of the mold compound 106. The surface features 114 disrupt the planarity of the exterior surface of the mold compound 106, and are arranged along a direction which is transverse to a lengthwise extension of the metal leads 104. The term ‘transverse’ as used herein with respect to the direction of each feature 114 formed in the exterior surface of the mold compound 106 means acting, lying, or being across the lengthwise extension of a corresponding metal lead 104. The lengthwise extension of one metal lead 104 is labelled ‘x1’ in FIG. 1, and the direction of one surface feature 114 which disrupts the planarity of the exterior surface of the mold compound 106 and which runs transverse to the lengthwise extension ‘x1’ of the metal lead 104 is labelled ‘y1’ in FIG. 1. For each combination of metal lead 104 and surface feature 114 arranged along a direction transverse to the lengthwise extension of the metal lead 104, the lengthwise extension direction of the metal lead 104 and the lengthwise extension direction of the surface feature 114 may or may not enclose an angle of 90°. In other words, in some cases, the lengthwise extension direction of a metal lead 104 may be orthogonal to the lengthwise extension direction of a surface feature 114 which runs transverse to the lengthwise extension of that metal lead 104, whereas in other cases, the lengthwise extension direction of a metal lead 104 may not be orthogonal to the lengthwise extension direction of a surface feature 114 which runs transverse to the lengthwise extension of that metal lead 104.

The molded semiconductor package 100 may be manufactured by electrically connecting the metal leads 104 to the semiconductor die 102, e.g. via bond wires 108, followed by embedding the semiconductor die 102 and the metal leads 104 in the mold compound 106. The features 114 in the exterior surface of the mold compound 106 which disrupt the planarity of the exterior surface may be formed during the molding process or after. In one embodiment, the features 114 are formed in the exterior surface of the mold compound 106 by laser etching the exterior surface of the mold compound 106. In another embodiment, the features 114 are formed in the exterior surface of the mold compound 106 during embedding of the semiconductor die 102 and the metal leads 104 in the mold compound 106. For example, a rubber element may be placed in the jig used to mold the package 100. The rubber element has features which yield the surface features 114 during the molding process. In another embodiment, the features 114 are formed in the exterior surface of the mold compound 106 by polishing the exterior surface of the mold compound 106 after the molding process.

According to the embodiment illustrated in FIG. 1, the features 114 formed in the exterior surface of the mold compound 106 and which disrupt the planarity of the exterior surface 106 are grooves 116. The grooves 116 may be formed as a grid in the exterior surface of the mold compound 106.

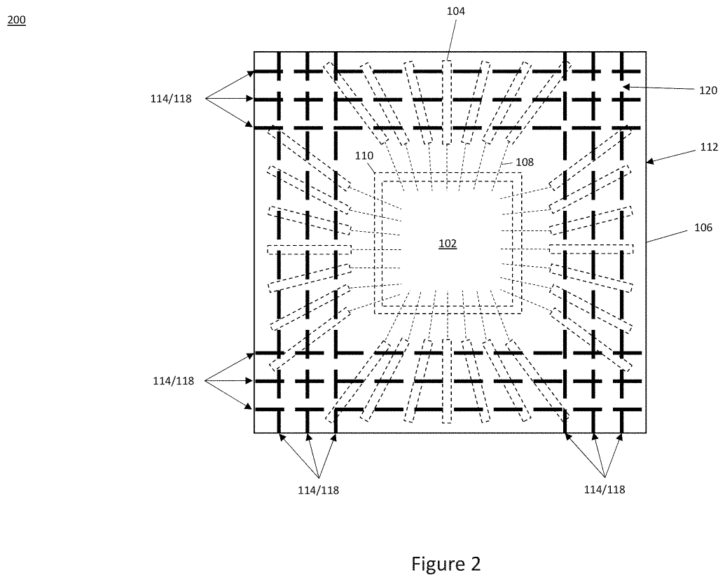

FIG. 2 illustrates a top plan view of another embodiment of a molded semiconductor package 200 in which the planarity of the exterior surface of the mold compound 106 is disrupted to reduce the integral characteristic of the oxide shrinkage. The embodiment illustrated in FIG. 2 is similar to the embodiment illustrated in FIG. 1. Different, however, at least one the features 114 formed in the exterior surface of the mold compound 104 is segmented into groove segments 118 which are separated from one another by an undisrupted portion 120 of the exterior surface of the mold compound 106.

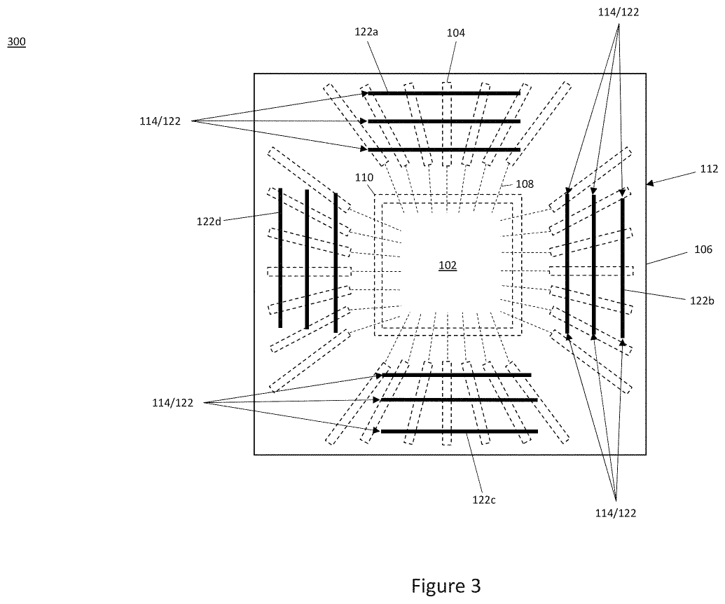

FIG. 3 illustrates a top plan view of another embodiment of a molded semiconductor package 300 in which the planarity of the exterior surface of the mold compound 106 is disrupted to reduce the integral characteristic of the oxide shrinkage. The embodiment illustrated in FIG. 3 is similar to the embodiment illustrated in FIG. 1. Different, however, at least one of the features 114 formed in the exterior surface of the mold compound 106 is segmented into a groove segments 122 having four linear groove segments 122a-122d each one of which runs along a different side of the semiconductor die 102 in a vertical projection (coming out of the page in FIG. 3) which is perpendicular to the exterior surface of the mold compound 106.

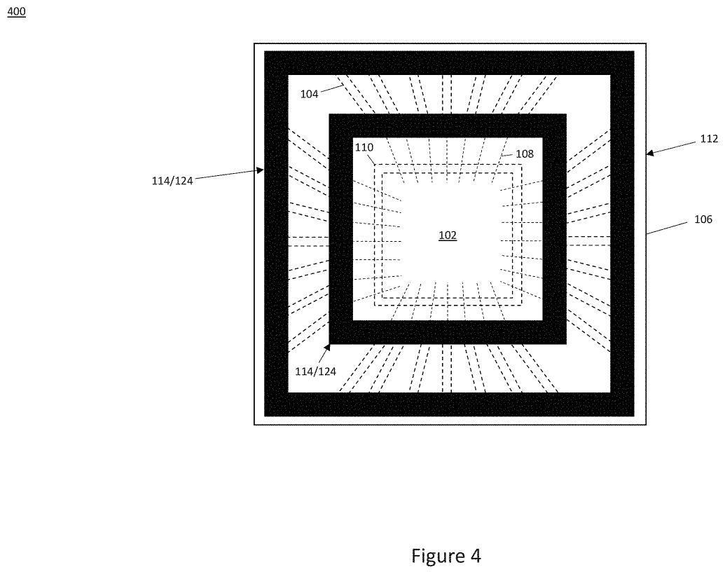

FIG. 4 illustrates a top plan view of another embodiment of a molded semiconductor package 400 in which the planarity of the exterior surface of the mold compound 106 is disrupted to reduce the integral characteristic of the oxide shrinkage. The embodiment illustrated in FIG. 4 is similar to the embodiment illustrated in FIG. 1. Different, however, at least one of the features 114 formed in the exterior surface of the mold compound 104 is a continuous structure 124 which surrounds the semiconductor die 102 in a vertical projection (coming out of the page in FIG. 4) perpendicular to the exterior surface of the mold compound 106. In one embodiment, each continuous structure 124 is formed in the exterior surface of the mold compound 106 as a concentric square centered on the semiconductor die 102 and surrounding the semiconductor die 102 in the vertical projection.

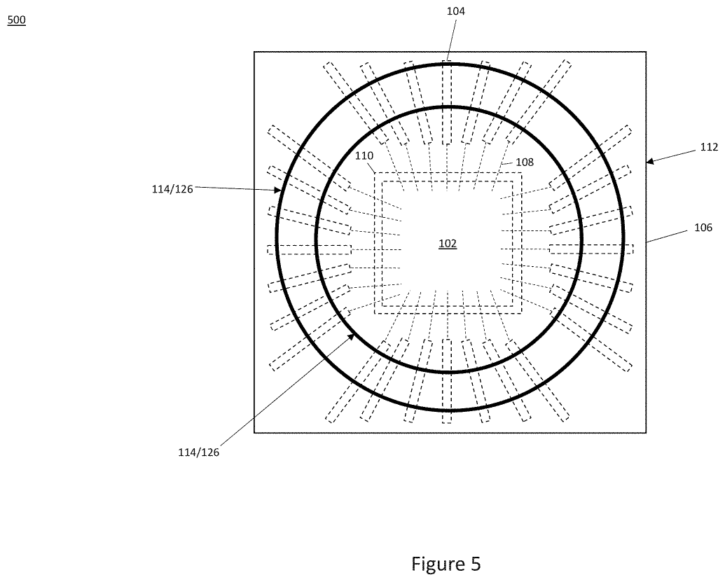

FIG. 5 illustrates a top plan view of another embodiment of a molded semiconductor package 500 in which the planarity of the exterior surface of the mold compound 106 is disrupted to reduce the integral characteristic of the oxide shrinkage. The embodiment illustrated in FIG. 5 is similar to the embodiment illustrated in FIG. 4. Different, however, at least one of the features 114 formed in the exterior surface of the mold compound 104 is a concentric circle 126 centered on the semiconductor die 102 and surrounding the semiconductor die 102 in a vertical projection (coming out of the page in FIG. 5) perpendicular to the exterior surface of the mold compound 106.

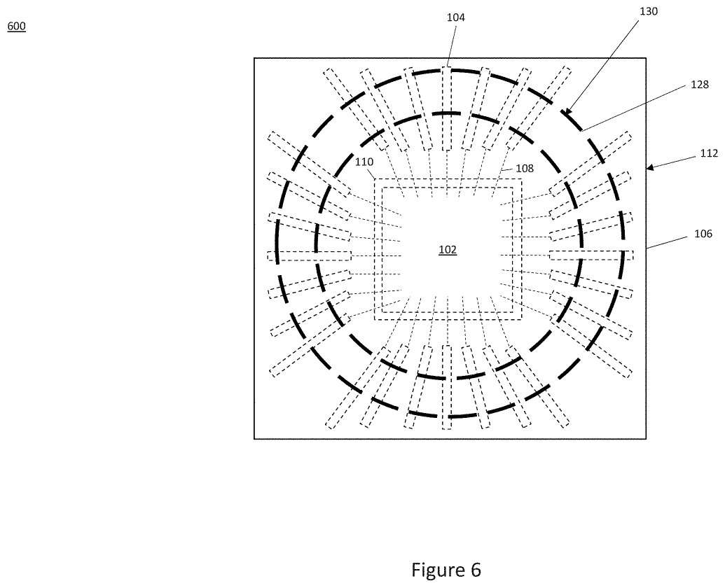

FIG. 6 illustrates a top plan view of another embodiment of a molded semiconductor package 600 in which the planarity of the exterior surface of the mold compound 106 is disrupted to reduce the integral characteristic of the oxide shrinkage. The embodiment illustrated in FIG. 6 is similar to the embodiment illustrated in FIG. 5. Different, however, at least one of the concentric circles 126 formed in the exterior surface of the mold compound 106 and which surrounds the semiconductor die 102 in a vertical projection (coming out of the page in FIG. 6) is segmented into curvilinear groove segments 128 which are separated from one another by an undisrupted portion 130 of the exterior surface of the mold compound 106 and surround the semiconductor die 102 in the vertical projection.

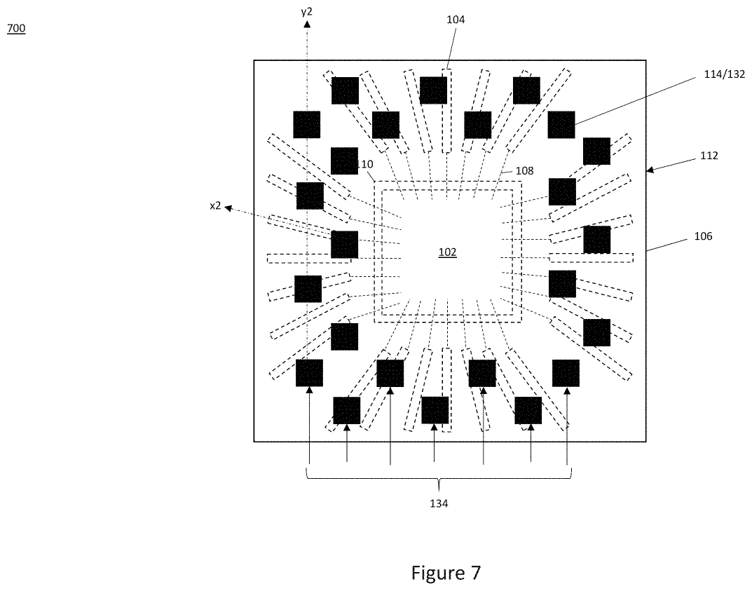

FIG. 7 illustrates a top plan view of another embodiment of a molded semiconductor package 700 in which the planarity of the exterior surface of the mold compound 106 is disrupted to reduce the integral characteristic of the oxide shrinkage. According to this embodiment, the features 114 formed in the exterior surface of the mold compound 106 are dimples 132. The dimples 132 may be arranged in rows 134 each of which runs along a direction which is transverse to the lengthwise extension of a metal lead 104. The lengthwise extension of one metal lead 104 is labelled ‘x2’ in FIG. 7, and the direction of one row 134 of dimples 132 which disrupts the planarity of the exterior surface of the mold compound 106 and which runs transverse to the lengthwise extension ‘x2’ of the metal lead 104 is labelled ‘y2’ in FIG. 7. For each combination of metal lead 104 and row 134 of dimples 132 arranged along a direction transverse to the lengthwise extension of the metal lead 104, the lengthwise extension direction of the metal lead 104 and the lengthwise extension direction of the row 134 of dimples 132 may or may not enclose an angle of 90°, i.e., may or may not run orthogonal to one another.

The embodiments described above in connection with FIGS. 1 through 7 provide features 114 formed in the exterior surface of the mold compound 106 which disrupt the planarity of the exterior surface, thereby reducing the integral characteristic of the oxide shrinkage. The features 114 formed in the exterior surface of the mold compound 106 are shown formed above the metal leads 104 in FIGS. 1 through 7. Separately or in combination, additional features (not shown in FIGS. 1 through 7) may be formed in the exterior surface of the mold compound 106 which disrupt the planarity of the exterior surface and which are disposed above the semiconductor die 102 embedded in the mold compound 106. Features formed in the exterior surface of the mold compound 106 above the semiconductor die 102 may have the same or different size, shape, dimensions and/or configuration as the illustrated features 114 formed in the exterior surface of the mold compound 106 above the metal leads 104. For example, the features 114 formed in the exterior surface of the mold compound 106 above the metal leads 104 may be continuous or segmented grooves, whereas features formed in the exterior surface of the mold compound 106 above the semiconductor die 102 may also be continuous or segmented grooves or may instead be dimples, for example. Conversely, the features 114 formed in the exterior surface of the mold compound 106 above the metal leads 104 may be dimples and features formed in the exterior surface of the mold compound 106 above the semiconductor die 102 may be continuous or segmented grooves. Yet other combinations of sizes, shapes, dimensions and/or configurations of the features 114 formed in the exterior surface of the mold compound 106 above the metal leads 104 and above the semiconductor die 102 may be realized.

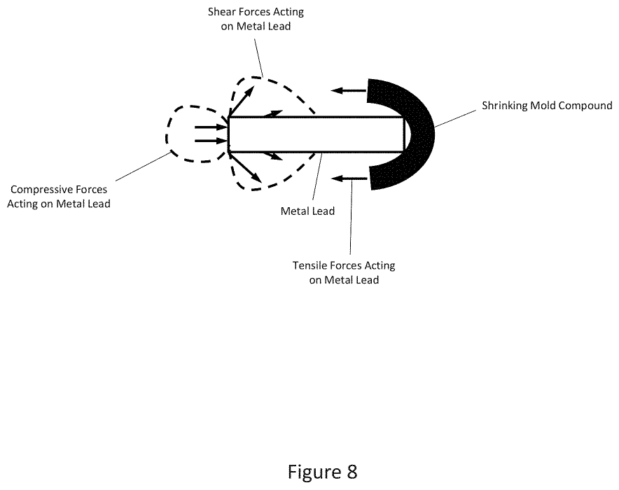

FIG. 8 illustrates the stress forces acting on a metal lead of a molded semiconductor package and caused by oxidation of the exterior surface of the mold compound. As the exterior surface of the mold compound oxidizes, the mold compound shrinks and pulls away from the metal lead. The shrinking mold compound induces tensile, compressive and shear forces which act on the metal lead and possibly on a semiconductor inside the molded package. The delamination force is the sum of all elementary shrinkage along a path.

The inventors have determined that the tensile, compressive and shear force components of the delamination force caused by the oxidation of the mold compound 106 are expected to peak near the tip (end) of the metal lead as shown in FIG. 8, initiating delamination at the lead tip. Tensile forces caused by shrinkage of the oxidized mold compound act at the top and bottom surface of the metal lead, pushing the metal lead toward the center of the molded package. Adjacent metal lead may also be forced together, resulting in compressive forces acting between the metal leads. Due to these stress mechanisms, the interface stress at a metal lead may be larger for thicker oxide and for larger shrinkage because a larger force acts on the metal lead.

The total interface stress acting on the metal lead is the sum of the normal tensile stress σₙ and the total shear stress σₜₛ, and is given by:

σᵢₙₜ=σₙ+σₜₛ (1)

The total shear stress σₜₛ can be expressed as:

σₜₛ=\sqrt{σ_{xz}²+σ_{yz}²} (2)

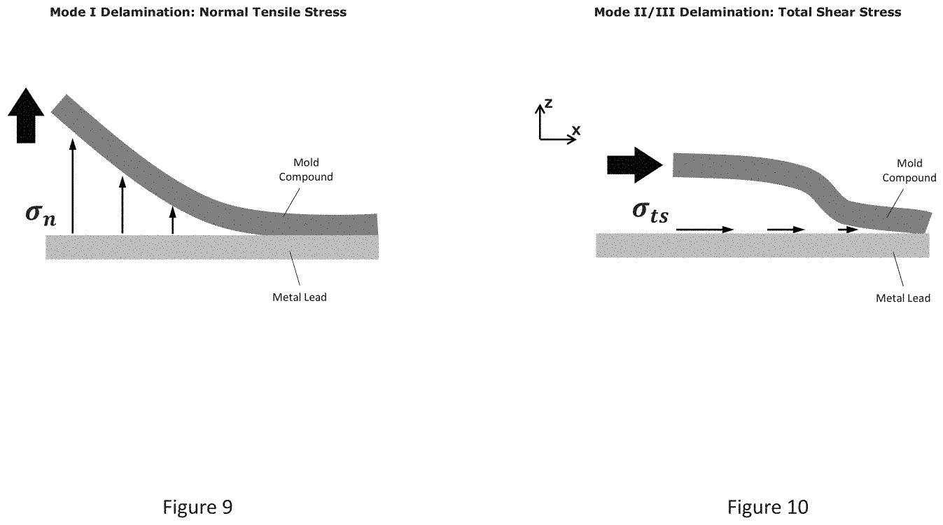

FIG. 9 illustrates the normal tensile stress aₙ and FIG. 10 illustrates the total shear stress σₜₛ=\sqrt{σ_{xz}²+σ_{yz}²}. The total interface stress given by equation (1) provides a way for evaluating the combined delamination risk due to peeling (FIG. 9) and shear/torsion (FIG. 10).

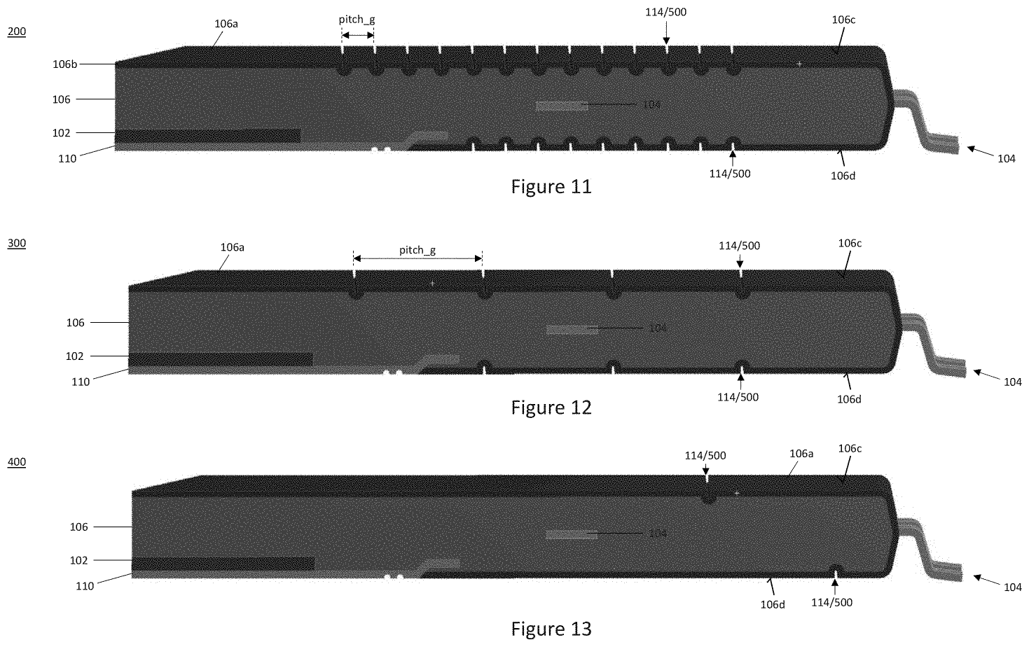

FIGS. 11 through 13 illustrate respective partial sectional views of additional embodiments of molded semiconductor packages 200, 300, 400 in which the planarity of the exterior surface 106a of the mold compound 106 is disrupted to reduce the integral characteristic of the oxide shrinkage. The exterior oxidized part 106b of the mold compound 106 is plainly visible in the sectional views of FIGS. 11 through 13. In each of these embodiments, the features 114 formed in the exterior surface 106a/oxidized part 106b of the mold compound 106 to disrupt the planarity of the oxidized exterior surface 106a/106b are grooves 500. Although FIGS. 11 through 13 each show the grooves 500 formed in the exterior surface 106a/oxidized part 106b of the mold compound 106 above only the metal leads 104, additional grooves (not shown) or other type of feature such as dimples may be formed in the exterior surface 106a/oxidized part 106b of the mold compound 106 above the semiconductor die 102.

Each groove 500 is arranged along a direction (coming out of the page in FIGS. 11 through 13) which is transverse to a lengthwise extension (across the page in FIGS. 11 through 13) of one or more metal leads 104. The top main surface 106c and/or the bottom main surface 106d of the mold compound 106 may include grooves 500.

The groove pitch (groove-to-groove spacing) pitch_g in FIG. 13 is about 2× the groove pitch in FIG. 12, and the groove pitch in FIG. 12 is about 4× the groove pitch in FIG. 11. Accordingly, the molded semiconductor package 200 in FIG. 11 has a higher groove density than the molded semiconductor package 300 in FIG. 12, and the molded semiconductor package 300 in FIG. 12 has a higher groove density than the molded semiconductor package 400 in FIG. 13. By increasing the number (density) of grooves 500 formed in the exterior surface 106a/oxidized part 106b of the mold compound 106, the area of high tensile stress near the tips of the metal leads 104 decreases. Stress simulations for the molded semiconductor packages 200, 300, 400 illustrated in FIGS. 11 through 13 shows that the molded semiconductor package 200 in FIG. 11 has about a 35% reduction in the maximal value of the interface stress, which occurs near the tips of the metal leads 104 as previously explained herein, as compared to the molded semiconductor package 400 in FIG. 13. The metal leads 104 may be of either the leaded or leadless type.

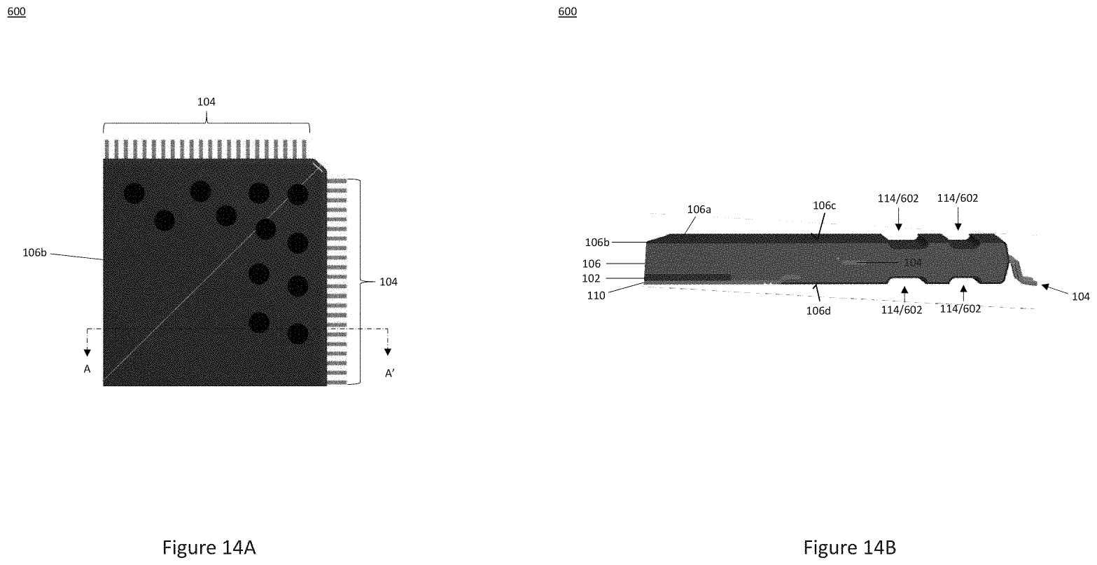

FIGS. 14A illustrates a partial top plan view of another embodiment of a molded semiconductor package 600 in which the planarity of the exterior surface 106a/oxidized part 106b of the mold compound 106 is disrupted to reduce the integral characteristic of the oxide shrinkage, and FIG. 14B illustrates a partial sectional view of the molded semiconductor package 600 taken along the line labelled A-A′ in FIG. 14A. According to this embodiment, the features 114 formed in the exterior surface 106a/oxidized part 106b of the mold compound 106 to disrupt the planarity of the exterior surface 106a are dimples 602. Although FIG. 14 shows the dimples 602 formed in the exterior surface 106a/oxidized part 106b of the mold compound 106 above only the metal leads 104, additional dimples or other type of feature such as grooves may be formed in the exterior surface 106a/oxidized part 106b of the mold compound 106 above the semiconductor die 102. The dimples 602 may be formed in the top main surface 106c and/or the bottom main surface 106d of the mold compound 106. Stress simulations for the molded semiconductor package 600 illustrated in FIG. 14 shows that the molded semiconductor package 600 in FIG. 14 has about a 25% reduction in the maximal value of the interface stress, which occurs near the tips of the metal leads 104 as previously explained herein, as compared to the same molded semiconductor package but without the dimples 602. The metal leads 104 are illustrated generically, and may be of either the leaded or leadless type.

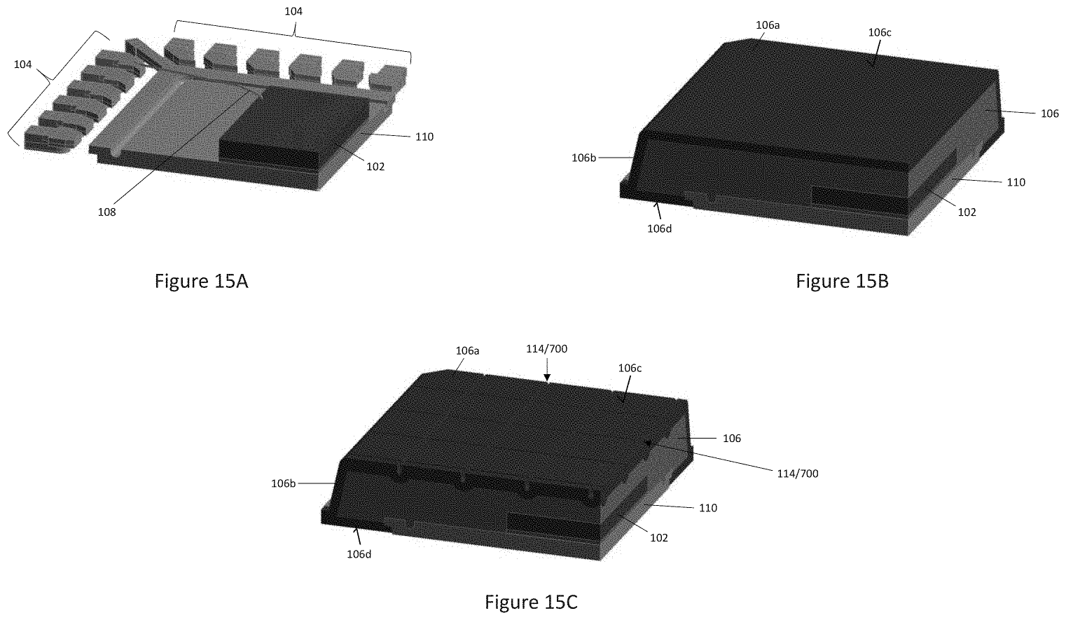

FIGS. 15A through 15C illustrate respective partial sectional views associated with different stages of a method of manufacturing a molded semiconductor package in which the planarity of the exterior surface 106a/oxidized part 106b of the mold compound 106 is disrupted to reduce the integral characteristic of the oxide shrinkage. FIG. 15A shows the package structure after a semiconductor die 102 is attached to a substrate such as a die pad 110 of leadframe, and after a bond wire bond 108 is connected between the semiconductor die 102 and one of the metal leads 104 of the package. FIG. 15B shows the package structure after all of the metal leads 104 are electrically connected to the semiconductor die 102, and after embedding the semiconductor die 102 and the metal leads 104 in a mold compound 106. The metal leads 104 are illustrated generically, and may be of either the leaded or leadless type.

The exterior surface 106a of the mold compound 106 may oxidize over time, resulting in an exterior oxidized part 106b as previously explained herein. FIG. 15C shows the package structure after features 114 are formed in the exterior surface 106a/oxidized part 106b of the mold compound 106. The features 114 disrupt the planarity of the exterior surface 106a/oxidized part 106b of the mold compound 106 and are arranged along a direction which is transverse to the lengthwise extension of the metal leads 104, as previously described herein. The features 114 may be formed above only the metal leads 104, above only the semiconductor die 102, or above the metal leads 104 and above the semiconductor die 102 (as shown in FIG. 15C). The features 114 are illustrated as grooves 700 formed as a grid in the exterior surface 106a/oxidized part 106b of the mold compound 106. Stress simulations for the molded semiconductor package illustrated in FIG. 15C shows that the molded semiconductor package has about a 16% reduction in the maximal value of the interface stress, which occurs near the tips of the metal leads 104 as previously explained herein, as compared to the same molded semiconductor package but without the grooves 700.

In FIG. 15C, the grooves 700 formed in the exterior surface 106a/oxidized part 106b of the mold compound 106 above the semiconductor die 102 form part of the same grid as the grooves 700 formed in the exterior surface 106a/oxidized part 106b of the mold compound 106 above the metal leads 104. In general, features 114 formed in the exterior surface 106a/oxidized part 106b of the mold compound 106 above the semiconductor die 102 may gave the same or different size, shape, dimensions and/or configuration as features 114 formed in the exterior surface 106a/oxidized part 106b of the mold compound 106 above the metal leads 104.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A molded semiconductor package, comprising:
a semiconductor die embedded in a mold compound;
a plurality of metal leads embedded in the mold compound and electrically connected to the semiconductor die; and
a first plurality of features formed in an exterior surface of the mold compound, the first plurality of features disrupting a planarity of the exterior surface of the mold compound and being arranged along a direction which is transverse to a lengthwise extension of the plurality of metal leads.

2. The molded semiconductor package of claim 1, wherein the first plurality of features formed in the exterior surface of the mold compound comprises a first plurality of grooves formed in the exterior surface of the mold compound.

3. The molded semiconductor package of claim 2, wherein at least one groove of the first plurality of grooves is continuous and surrounds the semiconductor die in a vertical projection which is perpendicular to the exterior surface of the mold compound.

4. The molded semiconductor package of claim 2, wherein at least one groove of the first plurality of grooves is segmented into groove segments which are separated from one another by an undisrupted portion of the exterior surface of the mold compound.

5. The molded semiconductor package of claim 4, wherein each groove which is segmented into groove segments has four linear groove segments each one of which runs along a different side of the semiconductor die in a vertical projection which is perpendicular to the exterior surface of the mold compound.

6. The molded semiconductor package of claim 4, wherein each groove which is segmented into groove segments has a plurality of curvilinear groove segments surrounding the semiconductor die in a vertical projection which is perpendicular to the exterior surface of the mold compound.

7. The molded semiconductor package of claim 2, wherein the first plurality of grooves comprises a plurality of concentric squares centered on the semiconductor die and surrounding the semiconductor die in a vertical projection which is perpendicular to the exterior surface of the mold compound.

8. The molded semiconductor package of claim 2, wherein the first plurality of grooves comprises a plurality of concentric circles centered on the semiconductor die and surrounding the semiconductor die in a vertical projection which is perpendicular to the exterior surface of the mold compound.

9. The molded semiconductor package of claim 1, wherein the first plurality of features formed in the exterior surface of the mold compound comprises a first plurality of dimples formed in the exterior surface of the mold compound, and wherein the first plurality of dimples are arranged in rows which run along a direction which is transverse to the lengthwise extension of the plurality of metal leads.

10. The molded semiconductor package of claim 1, wherein the first plurality of features formed in the exterior surface of the mold compound comprises a first plurality of grooves formed as a grid in the exterior surface of the mold compound.

11. The molded semiconductor package of claim 1, wherein the first plurality of features disrupts the planarity of the exterior surface of the mold compound above the plurality of metal leads.

12. The molded semiconductor package of claim 11, further comprising a second plurality of features formed in the exterior surface of the mold compound, the second plurality of features disrupting the planarity of the exterior surface of the mold compound above the semiconductor die.

13. A method of manufacturing a molded semiconductor package, the method comprising:
electrically connecting a plurality of metal leads to a semiconductor die;
after electrically connecting the plurality of metal leads to the semiconductor die, embedding the semiconductor die and the plurality of metal leads in a mold compound; and
forming a first plurality of features in an exterior surface of the mold compound, the first plurality of features disrupting a planarity of the exterior surface of the mold compound and being arranged along a direction which is transverse to a lengthwise extension of the plurality of metal leads.

14. The method of claim 13, wherein the first plurality of features are formed in the exterior surface of the mold compound by laser etching the exterior surface of the mold compound.

15. The method of claim 13, wherein the first plurality of features are formed in the exterior surface of the mold compound during embedding of the semiconductor die and the plurality of metal leads in the mold compound.

16. The method of claim 13, wherein the first plurality of features are formed in the exterior surface of the mold compound by polishing the exterior surface of the mold compound.

17. The method of claim 13, wherein forming the first plurality of features in the exterior surface of the mold compound comprises forming a first plurality of continuous and/or segmented grooves in the exterior surface of the mold compound.

18. The method of claim 13, wherein forming the first plurality of features in the exterior surface of the mold compound comprises forming a plurality of continuous and/or segmented concentric squares or circles in the exterior surface of the mold compound and which are centered on the semiconductor die and surround the semiconductor die in a vertical projection which is perpendicular to the exterior surface of the mold compound.

19. The method of claim 13, wherein forming the first plurality of features in the exterior surface of the mold compound comprises forming a first plurality of dimples in the exterior surface of the mold compound, the first plurality of dimples being arranged in rows which run along a direction which is transverse to the lengthwise extension of the plurality of metal leads.

20. The method of claim 13, wherein the first plurality of features disrupts the planarity of the exterior surface of the mold compound above the plurality of metal leads, the method further comprising:
forming a second plurality of features in the exterior surface of the mold compound, the second plurality of features disrupting the planarity of the exterior surface of the mold compound above the semiconductor die.
